(19) United States
(12) Patent Application Publication
(10) Pub. No.: US 2009/0008364 A1
(43) Pub. Date: Jan. 8, 2009

(54) Method and Device for Etching Substrates Contained in an Etching Solution

(75) Inventors: Juergen Schweckendiek, Nuernberg (DE); Joerg Franzke, Neumarkt (DE); Matthias Niese, Neumarkt (DE); Juergen Osterkamp, Burgthann (DE)

Correspondence Address: KANESAKA BERNER AND PARTNERS LLP, 1700 DIAGONAL RD, SUITE 310, ALEXANDRIA, VA, 22314-2848, US

(73) Assignee: Astec Halbleitertechnologie GmbH, Berg (DE)

(21) Appl. No.: 11/792,343

(22) PCT Filed: Dec. 7, 2005
(86) PCT No.: PCT/EP2005/013112

§ 371 Date: Aug. 2, 2007

(30) Foreign Application Priority Data
Dec. 8, 2004 (DE) 10 2004 059 266.7
Apr. 6, 2005 (DE) 10 2005 015 758.0

(51) Int. Cl. B44C 1/22; H01L 21/306

(52) U.S. Cl. 216/83; 156/345.11

(57) ABSTRACT

The invention relates to a method for etching substrates (4) received in an etching solution (2). Said method comprises the following steps: A basin (1) which can receive the etching solution (2) is prepared, the substrate (4) is completely immersed in the etching solution (2), a flow which surrounds the substrate (4) is produced and the speed and/or direction of the flow can be periodically altered.

The invention relates to a method and a device for etching substrates contained in an etching solution as defined in the preamble of patent claims 1 and 21.

In accordance with the state of technology, substrates made of silicon are wetchemical etched to remove saw damage, to reduce the thickness of the substrates or to design the surface. A distinction is made between the so-called “acid etching” and the “alkaline etching.” In particular, etching can be done with a batch method by which a plurality of substrates placed in a tray are immersed in a basin containing the etching solution for a specified period of time.

The substrates are used to make components, for example, integrated circuits or photovoltaic elements. With regard to the further processing, the making of a particularly clean and uniform surface is important.

In particular, acid etching is a strongly exothermal procedure during which heat and gas bubbles are released. Due to this, a temperature gradient can form in the etching solution. Furthermore, it is possible that the gases created during etching are not uniformly conducted off but concentrate in certain sections of the substrates. The formation of a heat gradient and/or an irregular conducting off of the reaction products created during etching causes locally different etching rates on the surface of the substrate. That is detrimental to the surface quality of the substrates.

To counteract this disadvantage, a transition was made in accordance with the state of technology from the usual holding of the substrates vertically in the etching solution to rotating around a horizontal axis and/or moving the substrates back and forth in a translation motion. The rotation and/or translation of the substrates contributes to a uniform removal of reaction products, in particular, gases.

The rotation and the translation of the substrates requires the provision of a special rotation and/or translation device. That is expensive and time consuming. Aside from that, the size of the substrates to be processed increases continuously. In particular, a rotation of square substrates as are usually used in the area of photovoltaic would require the enlargement of the conventional basin.

GB 2 316 366 A describes a method as well as a device for the etching of turbine blades. In this connection, horizontally arranged nozzles are provided in a container containing an etching solution. A continuous flow generated by the nozzles is diverted by deflector plates positioned vertically to this. Furthermore, a rotation device is provided with which the turbine blades are rotated in the etching solution.

DE 100 31 603 C2 describes a method during which an etching solution flows laminar to an edge of a semi-conductor disk. To avoid turbulence, flow conducting bodies which narrow the flow lines are provided in the area of the edge. The generation of a continuous flow is required to maintain the laminar flow.

DE 103 13 692 A1 discloses a device for the etching of substrates. In this connection, an etching solution is fed through a canal which empties below the substrates. A laminar flow body is located in the area of the mouth of the canal to create a homogenous flow profile. The substrates are contained in a rotation device with which they are rotated in the etching solution.

From DE 33 45 050 C2 a generic device as well as a generic method for the etching of circuit boards is known. In this connection, etching solution is fed through nozzles located underneath the circuit boards.

The object of the invention is to remove the disadvantages in accordance with the state of technology. In particular, a method and a device are to be specified for the etching of substrates contained in an etching solution which also permits the generation of a high surface quality in basins of conventional size even when large substrates are involved. In accordance with a further goal of the invention, the method and the device are to be as simple as possible and supply reproducible results.

This object is resolved by the features of claims 1 and 21. Useful embodiments result from the features of claims 2 to 20 and 22 to 32.

According to the invention, on the method side it is provided that the velocity and/or direction of the flow is/are changed periodically.

This can be used to avoid the formation of a temperature gradient and reproducible high surface qualities can be achieved. In particular, this can be used to improve the effectiveness of the removal of reaction products, in particular for gas bubbles with a certain minimum size.

In the sense of this invention, “substrates” are understood to mean in particular semi-conducting disks for which any kind of contamination with iron or other metals which would effect the semi-conducting properties in an undesired manner is to be avoided during their surface processing via etching.

According to an advantageous embodiment, the substrates are rinsed with a flow directed to the bottom of the basin. Such a flow counteracts a flow which forms by itself while the substrates are held essentially vertically in the basin during etching. Such a flow is directed from the bottom to a surface of the etching solution and is essentially caused by rising gas bubbles and by a temperature gradient caused by the exothermal reaction in the etching solution. An excellent surface quality of the substrates can be achieved in a surprisingly simple and inexpensive way with the generation as suggested by the invention of a flow which counteracts the flow created by the reaction during etching.

In advantageous arrangement, the substrates are rinsed with flows directed in at least two different directions diagonally to the bottom. This ensures a uniformly high surface quality particularly for large substrates. It has proven useful to rinse the substrates alternately with flows directed in different directions. This removes reaction products effectively and completely, particularly with large substrates.

According to a further embodiment, it is provided that the substrates are rinsed, preferably continuously, with a flow directed from the bottom to a level or a surface of the etching solution. This flow can also be directed in directions diagonal to the level of the etching solution. The downward flows directed to the bottom and the upward flows directed from the bottom to the level of the etching solution are usefully aligned so that they do not cross at least in a central portion of the basin containing the substrates. Each of the downward flows are directed to the central portion of the basin so that the substrates are rinsed with them. The downward flows are set up so that they would meet in the central portion if they were created simultaneously. A flow velocity of the downward flows is usefully faster than a flow velocity of the upward flows. The preferably pulsating and/or alternating downward flows effectively remove reaction products from the surface of the substrates and transport them to an area of the upward flows. The preferably continuous upward flows then transport the reaction products to an area of the basin, on the upper edge of the basin for example, where they are disposed of.

According to a further embodiment, it is provided that the substrates are rinsed with a flow directed essentially parallel to their surfaces. In a particularly effective way, this enables the removal of the reaction products which have collected in the cracks between the vertically arranged substrates.

According to a further embodiment, the substrates are rinsed with a horizontal flow. Naturally other flow patterns can also be used. The flow can also take a crooked path or be circulating when passing the substrates.

Furthermore, it has been proven to be advantageous when a quasi laminar or a turbulent flow is generated. This also increases the effectiveness of the removal of reaction products.

A flow velocity is usefully selected so that a uniform rate of removal of etching material is achieved over the entire level of the substrates contained essentially vertically in the basin. The selection of the flow velocity essentially depends on the etching rate. The etching rate in turn depends on a series of parameters, for example, the type of acid used, its concentration, its temperature, the geometry of the basin, and so on. It is part of specialized knowledge to set the velocity in a suitable way in dependence on the respectively selected parameters.

According to a further embodiment feature, it is provided that a velocity and/or direction of the flow is/are controlled by a specified profile. In this connection, the flow velocity can be controlled, for example, depending on the progression of the reaction or the temperature of the etching solution. The direction of the flow can also be controlled. Flow conducting elements can be provided for this in the basin. However, the direction of the flow can also be controlled by several nozzles or nozzle holders pointing in different directions. In this case, control can be achieved by setting the discharge velocity of the etching solution generated by the nozzles or nozzle holders.

It has proven to be useful when the flow is created by removal from a lower basin section and addition of etching solution in a higher basin section located in the vicinity of a circumferential edge of the basin. In this case, in reversal of the method known as per the state of technology, the etching solution overflowing from the upper basin edge is not removed, and instead the etching solution in a lower basin section in the vicinity of the bottom is removed through a outlet opening provided there. The feed in occurs in a upper basin section, for example, through the inlet openings provided there.

It has been shown to be useful when etching solution which is taken from the basin is returned to the circulation in the basin. In this connection, the etching solution which is taken from the basin can be conditioned. “Conditioning” is understood to mean that the etching solution is returned to a suitable specified state. It can be purified for this purpose. Aside from this, the pH value and/or the temperature of the etching solution can be set to a specified reference value. It has been shown to be advantageous in this connection when the removed etching solution is conducted through a conditioning basin for conditioning. The provision of a specified amount of etching solution counteracts fluctuations in the parameters which determine the effect of the etching solution.

According to a further embodiment, it is provided that the conditioned etching solution is cooled before it is fed in. For this purpose, it can be advantageously conducted through a heat exchanger on the way from the conditioning basin to the basin.

It has been shown to be useful when the conditioned etching solution is fed through an opening provided on the bottom of the basin. This causes a further flow which is directed against the flow. The velocity of the further flow is selected so that the flow directed to the bottom is maintained. Aside from this, the opening can be provided in a lower section of the basin in which an inlet of conditioning etching solution leaves the flow essentially unaffected. For this purpose, a means of flow conductance can also be provided in the basin which ensures maintenance of the flow directed to the bottom in the area of the substrates.

According to a further embodiment, it is provided that the flow is generated by a pump inserted in a bypass. An outlet opening of the bypass can be located in the lower basin section and an inlet opening of the bypass can be located in an upper basin section. When the pump is inserted in the bypass, a particularly uniform agitation of the etching solution is achieved stretching from the upper basin section to the lower basin section.

When a bypass is used, the conditioned etching solution can also be conducted into the bypass. This can be used to simplify the whole design. In particular, it is not necessary to provide a separate inlet opening for the conditioned etching solution in the area of the basin.

An acid etching solution preferably containing a mixture of two acids can be used as etching solution. The mixture preferably contains HF (hydrogen fluoride) as well as one further acid with which the silicon can oxidize.

According to a further provision of the invention, it is provided on the device side that a control unit is provided for periodic modification of the velocity and/or direction of the flow. By periodically modifying the velocity and/or the direction of the flow as provided by the invention, it is advantageous that a movement of the substrates can be omitted. A specified aligned flow is generated via the unit in the basin for the removal of the reaction products created during etching. A unit for the generation of a rotation and/or translation movement of the substrates in the basin can be omitted. The device provided by the invention makes it possible to continuously charge all surface sections of the substrates with an etching solution having a largely identical activity. Excellent results can be obtained with this etching substrates.

It has been shown to be useful when a unit has several nozzles. It has been shown to be particularly advantageous when the nozzles are arranged so that a flow directed essentially parallel to the surfaces of the substrates can be generated. This means that the nozzles are arranged in such a way that etching solution is rinsed through the gaps formed between the substrates. Furthermore, it is useful when the nozzles are arranged in such a way that a flow directed to the bottom of the basin and/or a horizontal flow can be generated. The suggested flow directions counteract the formation of a convection flow directed to the surface of the liquid which flow forms due to the reaction heat created during etching and leads to an uneven etching removal of the substrates.

According to an advantageous embodiment of the invention, the nozzles are directed diagonally to the bottom in at least two different directions. Furthermore, further nozzles can be provided in two different directions from the bottom to the level of the etching solution. In this connection, the nozzles are usefully arranged so that the flows discharged by the nozzles do not cross.

Using the, preferably programmable, controller, the substrates can be advantageously rinsed alternately with flows directed in different directions. This provides a particularly effective removal of reaction products from the surface of the substrates.

The controller unit can be used to activate according to a specified program pumps or valves, in particular shut-off valves, which are installed in front of the nozzles. By selecting the pumps to be activated and/or setting the valves, a flow velocity and/or direction can be set, changed, periodically changed or also regulated based on specified parameters, particularly when several nozzles with different nozzle alignments are provided.

Further, it has been shown to be useful that a plurality of nozzles arranged in a row are combined into one nozzle holder. This enables a uniform flow formation over a plurality of substrates contained in the basin.

According to a further embodiment, at least one flow conducting element is provided in the basin. The flow conducting element is preferably a wall which reaches between two side walls of the basin. Naturally several, preferably two, flow conducting elements opposite each other, in particular two walls opposite each other, can also be provided. The two walls located opposite each other are usefully arranged so that a tray for the substrates can be placed between them in the basin. The basin can be divided into areas of different flow velocity and/or direction with flow conducting elements. For example, two walls opposite each other can divide narrow areas on the longitudinal edge of the basin. Used etching solution in these narrow areas can flow in the direction of the basin edge, overflow at the basin edge and then be returned to the circulation to the basin particularly via nozzle holders.

According to a further advantageous embodiment, at least one pump is provided with which etching solution taken from the basin can be transported in the circulation to the nozzles. It has been shown to be useful that at least two nozzle holders are provided, wherein each nozzle holder is supplied with etching solution by a separate pump. A cooling unit can in turn be installed after each pump which in particular can be designed as a hose pump. The provision of several separate controllable nozzle holders enables the generation of a plurality of specified flow patterns as well as a particularly precise control and/or regulation of the flow in the basin.

Further advantageous embodiments of the device result from the features which have already been described for this method whose features can in this sense also be features on the device side.

Examples will now be used to describe the invention in more detail based on the drawings. The figures are listed below:

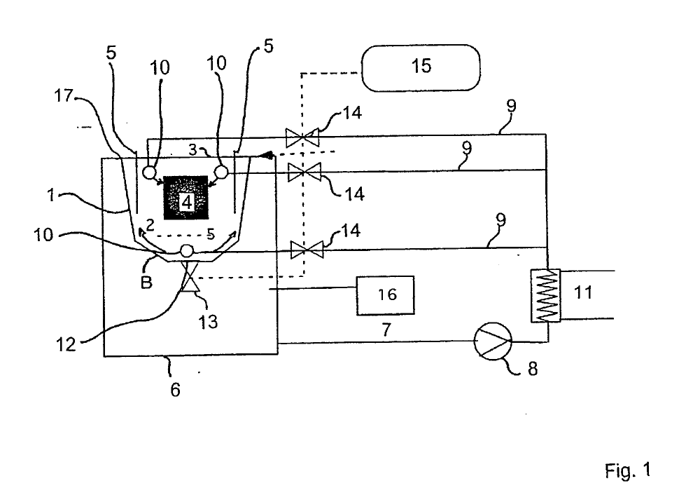

FIG. 1 a schematic presentation of a first example,

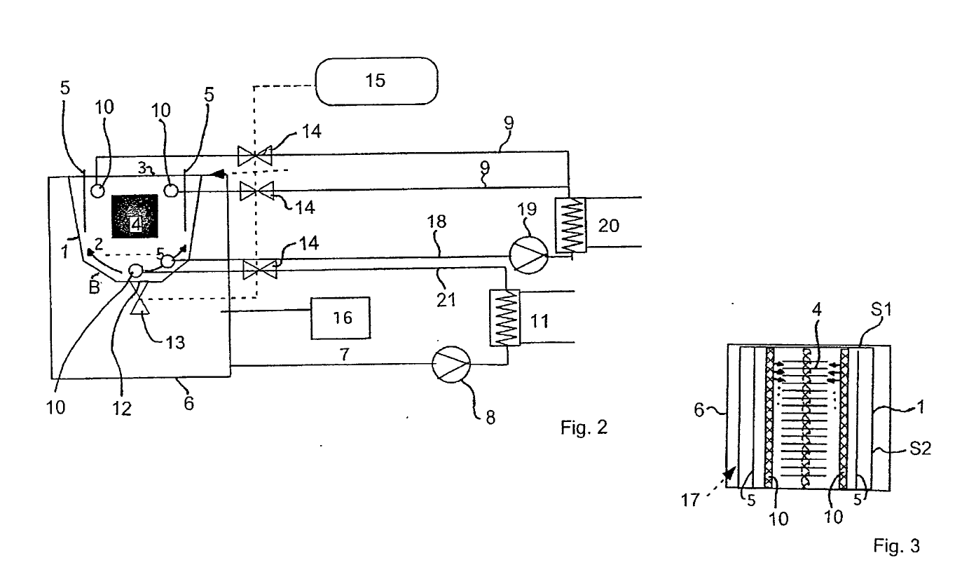

FIG. 2 a schematic presentation of a second example, and

FIG. 3 a top view of the basin as per FIG. 1 and FIG. 2.

The examples show an etching solution 2 contained in a basin 1. Below a level 3 of the etching solution 2, substrates 4 are immersed in the etching solution 2. The substrates 4 are contained in a tray (not shown here). As is particularly shown in the summarized view with FIG. 3, the substrates 4 are held in the tray in a vertically standing position in parallel arrangement; they are oriented parallel to the first side walls S1 of the basin 1. Flow conducting elements 5 are formed here in the form of two walls located opposite each other, which stretch parallel to the upper edge of the second side walls S2 of the basin 1. An intermediate space between the flow conducting elements 5 which are located opposite each other is dimensioned to be able to hold the tray with the substrates 4. A further flow conducting element 5, for example shaped in the form of a perforated plate, is located between a bottom B and the substrates 4. This flow conducting element 5 stretches essentially in the horizontal direction.

It has been shown to be advantageous when the basin 1 is located within a conditioning basin 6. An outlet tube 7 which is connected to the suction side of a pump 8 leads away from the conditioning basin. Inlet tubes 9 from the pressure side of the pump 8 lead to nozzle holders 10 which are located within the basin 1 below the level 3. Regarding the nozzle holders 10, these can be tubes on which a plurality of nozzles are provided next to each other. The nozzles form a row. It has been shown to be advantageous when the space between the nozzles is selected so that it corresponds to the space between the substrates 4 contained in the tray or a whole-number multiple thereof. A nozzle holder 10 can also have several rows of nozzles with which etching solution 2 can be discharged in different directions. Reference designator 11 identifies a first heat exchanger provided down current from pump 8. An outlet opening 12 on the bottom B of the basin 1 is usefully equipped with a valve, in particular a shut-off valve 13. Further valves, in particular further shut-off valves 14, can be inserted in the inlet tubes 9. The shut-off valve 13 and the further shut-off valves 14 are connected with a controller 15. The controller 15 can also be connected with the pump 8. Regarding the controller 15, this can be a programmable controller. A feeder unit 16 enables fresh etching solution 2 to be fed to the conditioning basin 6. Reference designator 17 identifies an overflow on the longitudinal edge of the second side walls S2. In a simple embodiment, the edge of the second side walls S2 is designed as a ripple edge.

The function of the device described in FIG. 1 is as follows:

Pump 8 pumps etching solution 2 from the conditioning basin 6 through the first heat exchanger 11 to the inlet tubes 9. The controller 15 can be used to bring the further shut-off valves 14 into a specified position via a program. This causes etching solution 2 to escape from the nozzle holders 10 installed down current under a specified pressure meaning a specified flow velocity.

The nozzles located in the upper nozzle holders 10 in the vicinity of the overflow 17 are oriented to the substrates 4, in other words in a direction pointing to the bottom B. As is particularly shown in the summarized view with FIG. 3, the flow vectors generated with the upper nozzle holders 10 are essentially parallel to the surface of the substrates 4. The flow generated with the upper nozzle holders 10 flows through the spaces between the substrates 4 and is then diverted to a lower flow conducting element 5, which is usefully designed as a perforated plate, in the direction of the second side walls S2 of the basin 1. The diversion of the flow is also supported by a lower nozzle holder 10 which usefully has two rows of nozzles. The two rows of nozzles point diagonally up in the direction of the overflow 17. Further, the flow is led through the upper flow conducting elements 5 in the direction of the overflow 17. The etching solution 2 overflows at overflow 17 and flows into the conditioning basin 6. The etching solution removed from basin 1 is conditioned in conditioning basin 6. This means its properties such as, for example, composition of the acid mixture, purity and similar, are set in the conditioning basin with suitable units to specified reference values. In this connection, fresh etching solution 2 can be added via the feeder unit 16, for example. The temperature of the etching solution 2 is usefully set by the first heat exchanger 11 inserted in the inlet tubes 9. The flow velocity of the etching solution 2 can be controlled or regulated via the controller 15 by a suitable activation of further shut-off valves 14 and/or pump 8. In particular the controller 15 can be programmable so that specified flow profiles can also be generated. In this way the flow velocity of the etching solution 2 in the basin 1 can periodically increase and decrease, for example.

According to a particularly advantageous embodiment, the controller 15 controls the further shut-off valves 14 inserted in the inlet tubes 9 to the upper nozzle holders 10 so that pressure is applied alternately to the upper nozzle holders 10. This causes alternating downward flows diagonal to the bottom B. At the same time a shut-off valve 13 inserted in the inlet tube 9 to the lower nozzle holder 10 can be controlled in such a way that this creates upward flows continuously directed to the level 3 of the etching solution 2. As is particularly shown in FIG. 1, at least within a central area of the basin 1, the downward flows do not cross with the upward flows which are directed diagonally up in the direction of the second side walls S2 of the basin 1. The downward flows coming from the upper nozzle holders 10 can also be pulsating, wherein the upper nozzle holders 10 can also be alternately pulsating. The downward flows can be generated alternately with a period of 1 to 60 seconds, for example, preferable 3 to 10 seconds.

Regarding the examples shown in FIGS. 2 and 3, a bypass 18 is provided on the basin 1 in which bypass a further pump 19 is inserted with a second heat exchanger 20 installed afterwards. The flow is maintained here by the further pump 19, among others. A separate circulation is provided for the conditioning of etching solution 2 for which a conditioning inlet tube 21 leads from the conditioning basin 6 to the basin 1 and empties there in the vicinity of the bottom B.

The controller 15 can be used to control the shut-off valves 13, the pump 8 and the further pump 19 in such a way that, at least in the area of the substrates 4, a downward flow directed from the level 3 to the bottom B is continuously formed. An upward flow created by the pump 8 has a much slower velocity and has almost no effect on the present downward flows which are directed from the level 3 to the bottom B and which change their direction and/or velocity periodically.

The suggested method is particularly suitable for the acid etching of substrates 4, in particular silicon substrates. In this connection, an acid mixture containing HF (hydrogen fluoride) is used. Within the framework of this invention, it is naturally also possible to perform the described method with other acids or other bases.

### REFERENCE DESIGNATION LIST

1 Basin
2 Etching solution
3 Level
4 Substrate
5 Flow conducting element
6 Conditioning basin
7 Outlet tube
8 Pump
9 Inlet tube
10 Nozzle holder
11 First heat exchanger
12 Outlet opening
13 Shut-off valve
14 Further shut-off valve
15 Controller
16 Feeder unit
17 Overflow
18 Bypass
19 Further pump
20 Second heat exchanger
21 Conditioning inlet tube
S1 First side wall
S2 Second side wall
B Bottom

1. Method for the etching of substrates (4) contained in an etching solution (2) comprising of the following steps:
provision of a basin (1) containing the etching solution (2),
complete immersion of the substrates (4) in the etching solution (2),
generation of a directed flow in the etching solution (2) to rinse the substrates (4), wherein the velocity and/or direction of the flow is/are periodically changed,
characterized in that
the substrates (4) are rinsed with downward flows directed in at least two different directions, each in a central part of the basin and diagonal to the bottom (B).

2. Method as defined claim 1, wherein the substrates (4) are rinsed, preferably continuously, with a flow directed from the bottom (B) to a level (3) of the etching solution (2).

3. Method as defined in claim 1, wherein the substrates (4) are rinsed with a flow directed essentially parallel to their surface.

4. Method as defined in claim 1, wherein a quasi laminar or turbulent flow is generated as flow.

5. Method as defined in claim 1, wherein a velocity of the flow is selected so that a uniform rate of removal of etching material is achieved over the entire level of the substrates (4) contained essentially vertically in the basin (1).

6. Method as defined in claim 1, wherein the velocity and/or direction of the flow is/are controlled by a specified profile.

7. Method as defined in claim 1, wherein the flow is generated by a removal from a lower basin section and an addition of etching solution (2) in a higher basin section located in the vicinity of a circumferential edge (17) of the basin (1).

8. Method as defined in claim 1, wherein etching solution (2) removed from the basin (1) is returned to the circulation in the basin (1).

9. Method as defined in claim 1, wherein the etching solution (2) removed from the basin (1) is conditioned.

10. Method as defined in claim 1, wherein the removed etching solution (2) is conducted for conditioning through a conditioning basin (6).

11. Method as defined in claim 1, wherein the etching solution (2) is cooled before being added to the basin (1).

12. Method as defined in claim 1, wherein the conditioned etching solution (2) is fed through at least one opening (10) provided on the bottom (B) of the basin (1).

13. Method as defined in claim 1, wherein the flow is generated by a pump (19) inserted in a bypass (18).

14. Method as defined in claim 1, wherein the conditioned etching solution (2) is conducted to the bypass (18).

15. Method as defined in claim 1, wherein an acid etching solution is used as the etching solution (2).

16. Method as defined in claim 1, wherein the etching solution (2) contains a mixture of two acids.

17. Device for the etching of substrates (4) contained in an etching solution (2), with a basin (1) for receiving the etching solution (2) and a unit for completely immersing the substrates (4) in the etching solution (2),
wherein a unit for generating a directed flow for rinsing of the substrates (4) in the etching solution (2) is provided,
and wherein a controller unit (15) for the periodic change of the velocity and/or direction of the flow is provided,
characterized in that
the unit for generating a directed flow rinsing of the substrates (4) has at least two nozzles (10) directed in two different directions diagonally to the bottom and
in that the pumps or valves installed ahead of the nozzles (10) can be controlled with the controller unit (15) so that pressure is applied alternately to the nozzles (10) and, due to this, downward flows each directed alternately to a central part of the basin and diagonal to the bottom (B) are formed.

18. Device as defined in claim 17, wherein the nozzles are arranged in such a way that a flow can be generated directed essentially parallel to the surfaces of the substrates (4).

19. Device as defined in one of the claim 17, wherein a plurality of nozzles arranged in one row are combined into one nozzle holder (10).

20. Device as defined in one of the claim 17, wherein the controller unit (15) is programmable.

21. Device as defined in one of the claim 17, wherein at least one flow conducting element (5) is provided in the basin (1).

22. Device as defined in one of the claim 17, wherein at least one outlet opening (12) in a lower section of the basin (1) and nozzles (10) for adding etching solution (2) in an upper section located in the vicinity of a circumferential edge (17) of the basin (1) are provided.

23. Device as defined in one of the claim 17, wherein at least one pump (8, 19) is provided with which etching solution (2) taken from the basin (1) can be transported in the circulation to the nozzles.

24. Device as defined in one of the claim 17, wherein the outlet opening (12) is connected via an outlet tube (7) to a conditioning basin (6).

25. Device as defined in one of the claim 17, wherein a unit installed upstream from the nozzles (10) for cooling (11) the etching solution (2) is provided.
